(19) United States
(12) Patent Application Publication
(10) Pub. No.: US 2026/0033151 A1
(43) Pub. Date: Jan. 29, 2026

(54) DISPLAY PANEL AND DISPLAY DEVICE

(71) Applicant: HKC CORPORATION LIMITED, SHENZHEN (CN)

(72) Inventors: Yangchuan ZHOU, SHENZHEN (CN); Linlin QIU, SHENZHEN (CN); Lei JIANG, SHENZHEN (CN); Guangsheng LI, SHENZHEN (CN); Pei XU, SHENZHEN (CN)

(73) Assignee: HKC CORPORATION LIMITED, SHENZHEN (CN)

(21) Appl. No.: 19/268,627

(22) Filed: Jul. 14, 2025

(30) Foreign Application Priority Data
Jul. 29, 2024 (CN) 202411027356.4

(51) Int. Cl. H10K 59/122

(52) U.S. Cl. CPC H10K 59/122

(57) ABSTRACT

A display panel and a display device are provided. Each sub-pixel unit includes a sub-pixel and an isolation structure. A sidewall of the isolation structure includes a conductive portion and a shielding structure. The sidewall includes a first sidewall and a second sidewall. In the first sidewall, a distance between an edge of the shielding structure and an adjacent edge of the conductive portion is a first distance. In the second sidewall, a distance between an edge of the shielding structure and an adjacent edge of the conductive portion is a second distance. Within each sub-pixel unit, the second distance is greater than the first distance. Alternatively, in a planar direction substantially parallel to a pixel defining layer, an edge of the sub-pixel extending in a length direction of the evaporation source and an adjacent edge of the sidewall are obliquely disposed to each other.

### CROSS-REFERENCE TO RELATED APPLICATIONS

This application claims priority to Chinese Patent Application No. 202411027356.4, filed on Jul. 29, 2024 in the National Intellectual Property Administration of China, the contents of which are herein incorporated by reference in their entireties.

### TECHNICAL FIELD

The present disclosure relates to the field of display technologies, and in particular to a display panel and a display device.

### BACKGROUND

With the development of display technology, in order to reduce costs, a method without using the fine metal mask is adopted to form a cathode and a light-emitting layer in an organic light-emitting diode (OLED) display device. The cathode is formed through an evaporation process. The cathode may be electrically connected to each other through overlapping with an isolation structure.

However, such evaporation process may lead to a risk of poor overlapping between the cathode and the isolation structure.

### SUMMARY

A first technical solution adopted by the present disclosure may provide a display panel. The display panel may include a pixel defining layer and a plurality of sub-pixel units. The pixel defining layer may define a plurality of pixel openings. Each of the plurality of sub-pixel units may include a sub-pixel and an isolation structure. The sub-pixel may be disposed in a corresponding one of the plurality of pixel openings. A light-emitting layer and a cathode of the sub-pixel may be sequentially evaporated on the corresponding one of the plurality of pixel openings through an evaporation source. The isolation structure may protrude from the pixel defining layer and surround the corresponding one of the plurality of pixel openings. A sidewall of the isolation structure may include a conductive portion and a shielding structure shielding the conductive portion. In a planar direction substantially parallel to the conductive portion, the shielding structure may extend beyond the conductive portion. The conductive portion may be electrically connected to the sub-pixel. The sidewall may include a first sidewall and a second sidewall. An inner side surface of the first sidewall may extend in a displacement direction of the evaporation source. In the first sidewall, a distance between an edge of the shielding structure and an edge of the conductive portion that are adjacent to each other may be a first distance. In the second sidewall, a distance between an edge of the shielding structure and an edge of the conductive portion that are adjacent to each other may be a second distance. Within each of the plurality of sub-pixel units, the second distance may be greater than the first distance. Alternatively, in a planar direction substantially parallel to the pixel defining layer, an edge of the sub-pixel extending in a length direction of the evaporation source and an edge of the sidewall that are adjacent to each other may be obliquely disposed to each other.

A second technical solution adopted by the present disclosure may provide a display device that includes a main board and the display panel mentioned above.

### BRIEF DESCRIPTION OF THE DRAWINGS

In order to more clearly illustrate the technical solutions in some embodiments of the present disclosure, a brief introduction will be given below to the drawings required in the description of the embodiments. It is evident that the drawings described below are merely some embodiments of the present disclosure, and a person of ordinary skills in the art may obtain other drawings based on the following drawings without creative work.

FIG. 1 is a schematic structural view of an evaporation source and a restriction plate in the related art.

FIG. 2 is a schematic structural view of a display panel according to some embodiments of the present disclosure.

FIG. 3 is a schematic structural view of a first embodiment of a repeating unit according to the present disclosure.

FIG. 4 is a schematic structural view of a first embodiment of a sub-pixel unit according to the present disclosure.

FIG. 5 is a schematic sectional view at A-A and B-B in FIG. 3.

FIG. 6 is a schematic structural view of a second embodiment of a repeating unit according to the present disclosure.

FIG. 7 is a schematic structural view of a second embodiment of a sub-pixel unit according to the present disclosure.

FIG. 8 is a schematic structural view of a third embodiment of a repeating unit according to the present disclosure.

FIG. 9 is a schematic structural view of a fourth embodiment of a repeating unit according to the present disclosure.

FIG. 10 is a schematic structural view of a third embodiment of a sub-pixel unit according to the present disclosure.

FIG. 11 is a schematic structural view of a fifth embodiment of a repeating unit according to the present disclosure.

FIG. 12 is a schematic structural view of a fourth embodiment of a sub-pixel unit according to the present disclosure.

FIG. 13 is a schematic structural view of a display device according to some embodiments of the present disclosure.

### DETAILED DESCRIPTION

The following provides a detailed description of the technical solutions in some embodiments of the present disclosure with reference to the accompanying drawings.

In the following description, specific details such as particular system structures, interfaces, and technologies are presented for illustrative purposes and not for the purpose of limitation, to provide a thorough understanding of the present disclosure.

The technical solutions in some embodiments of the present disclosure will be clearly and completely described below with reference to the accompanying drawings. It is evident that the described embodiments are only part of the embodiments of the present disclosure and not all embodiments. Based on the embodiments of the present disclosure, all other embodiments obtained by a person of ordinary skills in the art without any creative work fall within the scope of the present disclosure.

The terms “first”, “second”, and “third” in the present disclosure are merely used for descriptive purposes and should not be construed as indicating or implying relative importance or implicitly indicating the quantity of the indicated technical features. Thus, the features limited by “first” “second” and “third” may explicitly or implicitly include at least one such feature. In the description of the present disclosure, “a plurality of” means at least two, for example, two, three, etc., unless specifically and explicitly limited otherwise. All directional indications (such as up, down, left, right, front, back, etc.) in the embodiments of the present disclosure are only used to explain the relative positional relationships, motion situations, etc. among the components under a specific posture (as shown in the figures). When the specific posture changes, the directional indications shall be changed accordingly. Furthermore, the terms “including” and “having” and any variations thereof, are intended to cover non-exclusive inclusion. For example, a process, method, system, product, or device that includes a series of steps or units is not limited to those explicitly listed steps or units but may further optionally include other steps or units not listed, or may further optionally include other inherent steps or units of such process, method, product, or device.

As referred to herein, “embodiment” means that a specific feature, structure, or characteristic described in connection with the embodiment may be included in at least one embodiment of the present disclosure. The appearance of the phrase in various places in the specification are not necessarily all referring to the same embodiment, nor are they mutually exclusive alternative embodiments. It is explicitly and implicitly understood by a person of ordinary skills in the art that the embodiments described herein may be combined with other embodiments.

Furthermore, it is to be understood that the use of the term “substantially” herein, unless otherwise defined with respect to a specific context, with respect to a numeric quantity or otherwise quantifiable relationship, e.g., perpendicularity or parallelism, is to be understood as indicating that quantity +−10%. Thus, for example, lines that are substantially perpendicular to one another may be at angles between 810 and 990 to one another. In a further example, dimensions that are substantially between 1 mm and 3 mm, for example, may range from 0.9 mm to 3.3 mm. In another example, an angle that is substantially in the range of 1 to 1.1 radians may be between 0.9 radians and 1.21 radians.

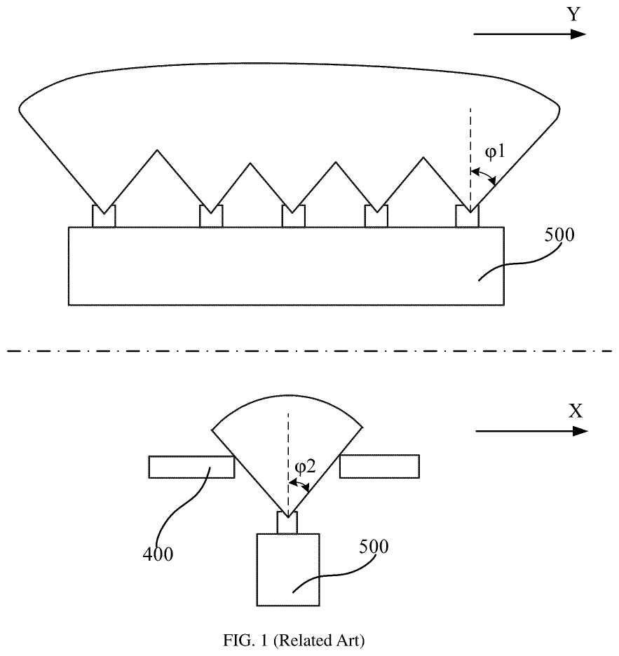

As shown in FIG. 1, FIG. 1 is a schematic structural view of an evaporation source and a restriction plate in the related art.

In an actual evaporation process, since an evaporation source 500 generates an evaporation cloud along a length direction Y of the evaporation source 500, an evaporation angle φ1 of an evaporation material may not be controlled along the length direction Y of the evaporation source 500. However, along a displacement direction X of the evaporation source 500 (i.e., a scanning direction of the evaporation source 500), an evaporation angle φ2 of the evaporation material may be controlled using a restriction plate 400 disposed on both sides of the evaporation source 500. Therefore, through arranging the restriction plate 400 above the evaporation source 500, the evaporation angle φ2 of the evaporation material along the displacement direction X of the evaporation source 500 may be enabled to be smaller than the evaporation angle φ1 of the same evaporation material along the length direction Y of the evaporation source 500. The greater the evaporation angle, the more easily the evaporation material may overlap with the conductive portion (not shown in FIG. 1). Compared with an edge of a cathode (not shown in FIG. 1) formed by the evaporation material along the length direction Y of the evaporation source 500, an edge of the cathode along the displacement direction X of the evaporation source 500 may be more likely to overlap with the conductive portion.

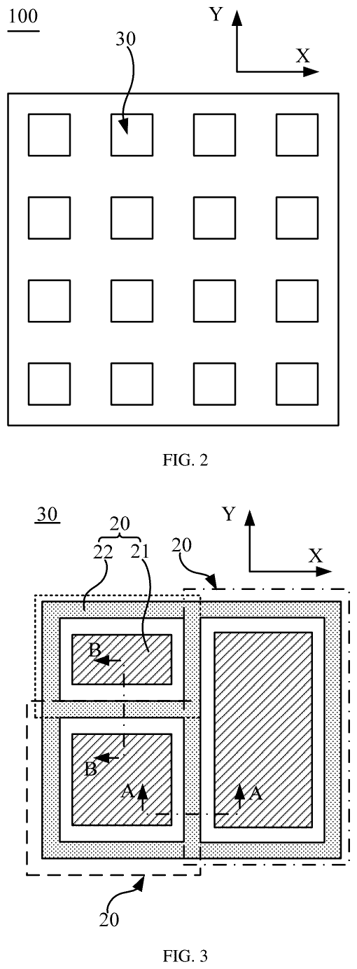

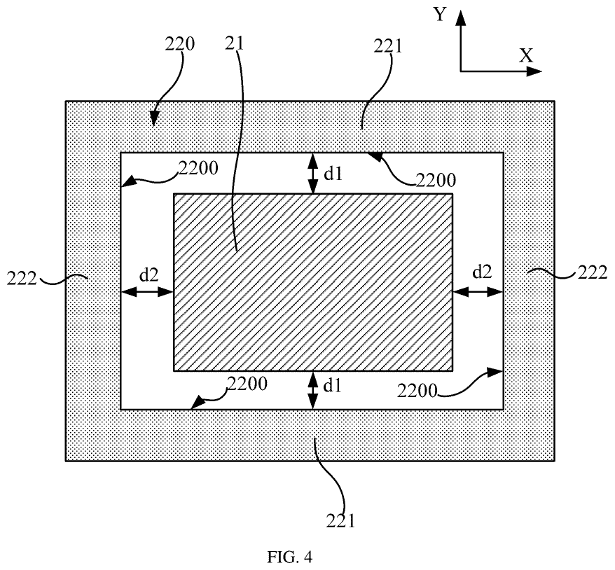

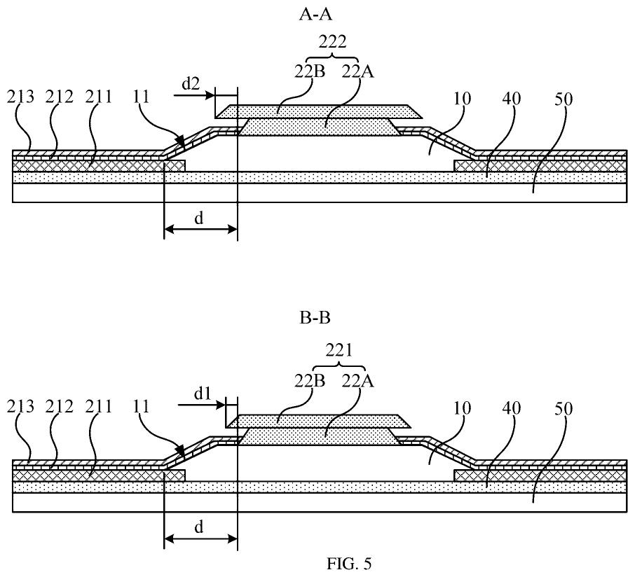

As shown in FIGS. 1-5. FIG. 2 is a schematic structural view of a display panel according to some embodiments of the present disclosure, FIG. 3 is a schematic structural view of a first embodiment of a repeating unit according to the present disclosure, FIG. 4 is a schematic structural view of a first embodiment of a sub-pixel unit according to the present disclosure, and FIG. 5 is a schematic sectional view at A-A and B-B in FIG. 3.

Based on the principle mentioned above, some embodiments of the present disclosure provide a display panel 100. The display panel 100 may include a pixel defining layer 10 and a plurality of sub-pixel units 20. The pixel defining layer 10 may define or include a plurality of pixel openings 11. Each of the plurality of sub-pixel units 20 may include a sub-pixel 21 and an isolation structure 22. The sub-pixel 21 may be disposed in a corresponding one of the plurality of pixel openings 11. Alight-emitting layer 212 and a cathode 213 of the sub-pixel 21 may be sequentially evaporated on the corresponding one of the plurality of pixel openings 11 through the evaporation source 500. The isolation structure 22 may protrude from the pixel defining layer 10 and surround the corresponding one of the plurality of pixel openings 11. A sidewall 220 of the isolation structure 22 may include a conductive portion 22A and a shielding structure 22B that shields the conductive portion 22A. In a planar direction substantially parallel to the conductive portion 22A, i.e. in a direction substantially parallel to a plane on which the conductive portion 22A is located, the shielding structure 22B may extend beyond the conductive portion 22A. The conductive portion 22A may be electrically connected to the sub-pixel 21. The sidewall 220 may include a first sidewall 221 and a second sidewall 222. An inner side surface 2200 of the first sidewall 221 may extend along the displacement direction X of the evaporation source 500. In the first sidewall 221, a distance between an edge of the shielding structure 22B and an edge of the conductive portion 22A that are adjacent to each other may be a first distance d1. In the second sidewall 222, a distance between an edge of the shielding structure 22B and an edge of the conductive portion 22A that are adjacent to each other may be a second distance d2. Within each of the plurality of sub-pixel units 20, the second distance d2 may be greater than the first distance d1. In the planar direction substantially parallel to the pixel defining layer 10, an edge of the sub-pixel 21 extending in the length direction Y of the evaporation source 500 and an edge of the sidewall 220 that are adjacent to each other may be obliquely disposed to each other.

Through arranging the second distance d2 to be greater than the first distance d1, a conductive overlap stability between the first sidewall 221 and the sub-pixel 21 may be ensured, while reducing a width by which the shielding structure 22B of the second sidewall 222 extends beyond the conductive portion 22A, thereby improving the conductive overlap stability between the second sidewall 222 and the sub-pixel 21. In addition, through arranging an edge of the sidewall 220 that is adjacent to the sub-pixel 21 to be inclined relative to the sub-pixel 21, the conductive overlap stability between the sidewall 220 and the sub-pixel 21 may be further enhanced.

The display panel may further include a flat layer 40 and a driving substrate 50. The flat layer 40 may be disposed on a side of the pixel defining layer 10 away from the isolation structure 22. The driving substrate 50 may be disposed on a side of the flat layer 40 away from the pixel defining layer 10. The driving substrate 50 may be configured to drive the sub-pixel 21 to emit light.

The pixel defining layer 10 may be configured to limit a position of the sub-pixel 21. The plurality of pixel openings 11 may be arranged at intervals.

Within each of the plurality of sub-pixel units 20, in a direction substantially parallel to the pixel defining layer 10, distances between each edge of the sub-pixel 21 and an adjacent edge of the conductive portion 22A may be equal to each other. In other words, within each of the plurality of sub-pixel units 20, distances between each edge of the sub-pixel 21 and a corresponding edge of the conductive portion 22A may be the same.

It should be noted that an effective light-emitting area of the sub-pixel 21 refers to an area of the anode 211 of the sub-pixel 21 exposed in the pixel opening 11. That is, the effective light-emitting area of the sub-pixel 21 may correspond to an area of an end portion of a side of the pixel opening 11 away from the isolation structure 22.

In the direction substantially parallel to the pixel defining layer 10, a distance between an edge of the sub-pixel 21 and an edge of the conductive portion 22A that are adjacent to each other may be defined as a preset distance d. That is, within each of the plurality of sub-pixel units 20, a distance between an edge of an end of the pixel opening 11 away from the isolation structure 22 and an edge of the adjacent conductive portion 22A that are adjacent to each other may be the preset distance d.

Each sub-pixel unit 20 may include one sub-pixel 21 and the isolation structure 22 surrounding the sub-pixel 21. The sub-pixel 21 and the isolation structure 22 may be arranged in a one-to-one correspondence. Each isolation structure 22 may surround and encircle one corresponding sub-pixel 21.

The sub-pixel 21 may include the anode 211, the light-emitting layer 212, and the cathode 213 that are sequentially stacked on one another. The light-emitting layer 212 and the cathode 213 may be sequentially evaporated on an upper surface of the anode 211 through the evaporation source 500.

In some embodiments, the sub-pixel 21 may be an organic light-emitting diode (OLED).

The isolation structure 22 may be configured to isolate each sub-pixel 21 in order to reduce a risk of pixel crosstalk. The conductive portion 22A of the isolation structure 22 may be electrically connected to the cathode 213 of the sub-pixel 21, such that the cathode 213 of each sub-pixel 21 may be electrically connected through the isolation structure 22, thereby facilitating a uniformity of the cathode 213.

The shielding structure 22B may be disposed on a surface of a side of the conductive portion 22A that is away from the pixel defining layer 10. An orthographic projection of the shielding structure 22B on the pixel defining layer 10 may cover an orthographic projection of the conductive portion 22A on the pixel defining layer 10. An area of the orthographic projection of the shielding structure 22B on the pixel defining layer 10 may be greater than an area of the orthographic projection of the conductive portion 22A on the pixel defining layer 10. The shielding structure 22B may be configured to adjust the evaporation angle.

In a direction substantially perpendicular to the pixel defining layer 10, a cross-section of the conductive portion 22A may substantially be a right trapezoid. A width of a side of the cross-section of the conductive portion 22A that is closer to the shielding structure 22B may be smaller than a width of a side of the cross-section of the conductive portion 22A that is farther from the shielding structure 22B.

A material of the shielding structure 22B and a material the conductive portion 22A are not limited herein and may be selected based on actual needs.

The isolation structure 22 may substantially have a ring-shaped structure. The ring-shaped structure may be a closed ring-shaped structure or a non-closed ring-shaped structure. The closed ring-shaped structure is mainly taken as an example for illustration herein.

It should be noted that in some embodiments of the present disclosure, the first sidewall 221 and the second sidewall 222 in each sub-pixel unit 20 may be distinguished according to an extending direction of the inner side surface 2200 of the sidewall 220. Within each sub-pixel unit 20, the number of the first sidewall 221 and the number of the second sidewall 222 may be more than one. The inner side surface 2200 of the sidewall 220 may refer to a side of the sidewall 220 facing the encircled sub-pixel 21.

In the planar direction substantially parallel to the pixel defining layer 10, an edge of the shielding structure 22B and an edge of the conductive portion 22A that are adjacent to each other within the same sidewall 220 may be substantially arranged in parallel. The distance between an edge of the shielding structure 22B and an edge of the conductive portion 22A that are adjacent to each other may be a preset value. The preset value may be greater than or equal to 0.3 μm and less than or equal to 1.2 μm, thereby ensuring that the conductive portion 22A may overlap with the sub-pixel 21 without excessively occupying a space between the sub-pixels 21.

For different sub-pixel units 20, distances between the edges of the sub-pixel 21 and the edges of the conductive portion 22A that are adjacent to each other in the planar direction substantially parallel to the pixel defining layer 10 may be the same or different, which is not limited herein and may be selected based on actual needs. It can be understood that in one of the plurality of sub-pixel units 20, the distance between an edge of the sub-pixel 21 and an edge of the conductive portion 22A that are adjacent to each other in the planar direction substantially parallel to the pixel defining layer 10 may be a first value. In another one of the plurality of sub-pixel units 20, the distance between an edge of the sub-pixel 21 and an edge of the conductive portion 22A that are adjacent to each other in the planar direction substantially parallel to the pixel defining layer 10 may be a second value. The first value and the second value may be the same or different, which is not limited herein and may be selected based on actual needs.

In some embodiments, in the planar direction substantially parallel to the pixel defining layer 10, an edge of the sub-pixel 21 and an edge of the sidewall 220 that are adjacent to each other may be substantially arranged in parallel. The inner side surface 2200 of the second sidewall 222 may extend in the length direction Y of the evaporation source 500.

The first distance d1 may be greater than or equal to 0.3 μm and less than or equal to 1.2 μm. The second distance d2 may be greater than or equal to 0.3 μm and less than or equal to 1.2 μm.

A difference between the second distance d2 and the first distance d1 may be less than or equal to 0.3 μm. It can be understood that, compared to the second sidewall 222 extending along the length direction Y of the evaporation source 500, the first sidewall 221 extending along the displacement direction X of the evaporation source 500 may have a better conductive overlapping effect with the cathode 213 of the sub-pixel 21. While a good overlapping is ensured between the first sidewall 221 and the sub-pixel 21, the distance between the edge of the shielding structure 22B and the edge of the conductive portion 22A that are adjacent to each other in the second sidewall 222 may be reduced. That is, the width by which the shielding structure 22B extends beyond the conductive portion 22A may be reduced, such that the cathode 213 may be more easily overlapped with the conductive portion 22A of the second sidewall 222. In this way, the cathode 213 of the sub-pixel 21 may realize the good conductive overlapping with the conductive portion 22A of each sidewall 220 of the isolation structure 22, thereby improving the conductive overlapping stability between the cathode 213 of the sub-pixel 21 and the conductive portion 22A of the isolation structure 22.

In some embodiments, the second distance d2 may be 0.6 μm to 1.2 μm and the first distance d1 may be 0.3 μm to 0.7 μm.

It should be noted that the preset value, the first distance d1, and the second distance d2 in the present disclosure all refer to the actual values, i.e., the distance between an edge of the shielding structure 22B and an edge of the conductive portion 22A that are adjacent to each other after the isolation structure 22 is fabricated.

The sub-pixel 21 may be substantially rectangular in shape. The isolation structure 22 may have a rectangular ring-shaped structure. An arrangement of the sub-pixel 21 is not limited herein and may be selected based on actual needs.

In some embodiments, the display panel 100 may include the sub-pixel 21 of three different colors. Each sub-pixel unit 20 may include the sub-pixel 21 of one color. The sub-pixel units 20 of three different colors form a rectangular repeating unit 30. An arrangement of the repeating unit 30 is not limited herein and may be selected based on actual needs. Among the sub-pixel units 20 of three different colors, two sub-pixel units 20 are disposed on the same side of the remaining one sub-pixel unit 20.

In the direction substantially perpendicular to the pixel defining layer 10, the sidewall 220 of the isolation structure 22 in one sub-pixel unit 20 may be partially overlapped with the sidewall 220 of the isolation structure 22 in an adjacent sub-pixel unit 20.

It should be understood that in other embodiments, the sub-pixel units 20 may have other arrangement patterns. The sub-pixel units 20 within the repeating unit 30 may have other arrangement patterns.

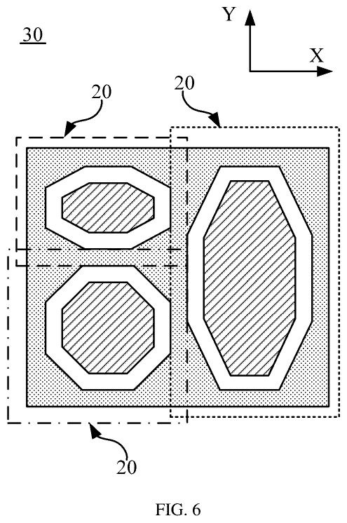

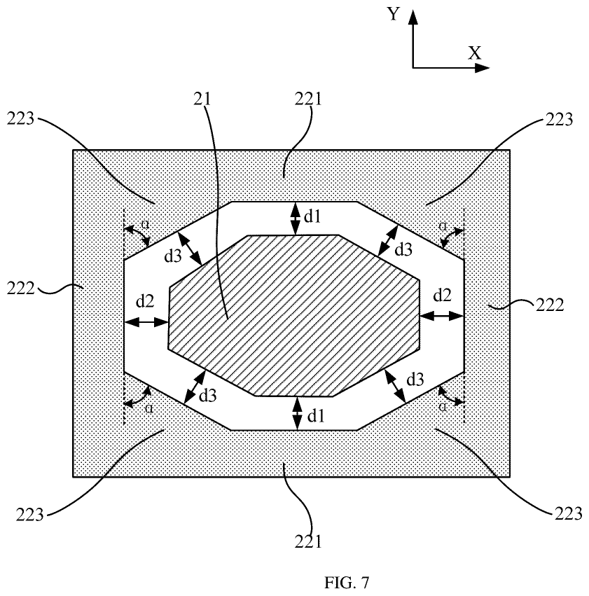

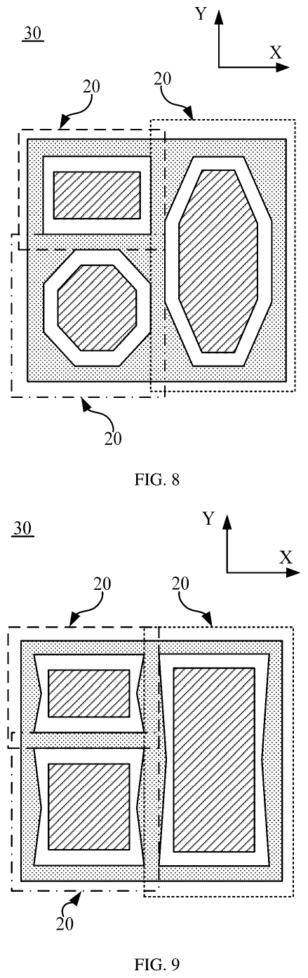

As shown in FIG. 2, FIG. 4, and FIGS. 6-8, FIG. 6 is a schematic structural view of a second embodiment of a repeating unit according to the present disclosure, FIG. 7 is a schematic structural view of a second embodiment of a sub-pixel unit according to the present disclosure, and FIG. 8 is a schematic structural view of a third embodiment of a repeating unit according to the present disclosure.

Compared with the first embodiment of the repeating unit 30 provided by the present disclosure, the second embodiment of the repeating unit 30 provided by the present disclosure may be substantially similar in structure, except that the sidewall 220 may further include an inclined sidewall 223. An extending direction of the inner side surface 2200 of the inclined sidewall 223 may intersect with both the length direction Y and the displacement direction X of the evaporation source 500.

In some embodiments, the sidewall 220 may include the first sidewall 221, the second sidewall 222, and the inclined sidewall 223. A difference between the second distance d2 and the first distance d1 may be less than 3 μm.

It should be noted that the first sidewall 221, the second sidewall 222, and the inclined sidewall 223 may be distinguished based on the extending direction of the inner side surface 2200 of the sidewall 220.

In the inclined sidewall 223, a distance between an edge of the shielding structure 22B and an edge of the conductive portion 22A that are adjacent to each other may be defined as a third distance d3. The third distance d3 may be greater than or equal to the first distance d1.

An end of the inclined sidewall 223 may be connected to the first sidewall 221. Another end of the inclined sidewall 223 may be connected to the second sidewall 222.

In some embodiments, the inner side surface 2200 of the first sidewall 221 may extend in the displacement direction X of the evaporation source 500 and the inner side surface 2200 of the second sidewall 222 may extend along the length direction Y of the evaporation source 500. The number of the inclined sidewall 223 may be at least one. When there are multiple inclined sidewalls 223, the inner side surfaces 2200 of the different inclined sidewalls 223 may have different extending directions. The third distances d3 among different inclined sidewalls 223 may be the same or different.

An included angle α between the extending direction of the inner side surface 2200 of the inclined sidewall 223 and the length direction Y of the evaporation source 500 may be greater than 5° and less than 20°, i.e., 5°<α<20°. Such design of the included angle α may help to minimize a reduction in an area of the pixel opening 11 surrounded by the isolation structure 22 due to the inclined sidewall 223, thereby ensuring that the cathode 213 of the sub-pixel 21 achieves the good conductive overlapping with the conductive portion 22A of the inclined sidewall 223 while maintaining a relatively minimal variation in the area of the pixel opening 11.

Through ensuring that the extending direction of the inner side surface 2200 of the inclined sidewall 223 is neither perpendicular to the length direction Y of the evaporation source 500 nor the displacement direction X of the evaporation source 500, the evaporation angle during the evaporation of the cathode 213 may be adjusted. In this way, the cathode 213 may be ensured to be electrically overlapped with at least part of the conductive portion 22A of the inclined sidewall 223. As a result, the cathode 213 of the sub-pixel 21 may be enabled to be reliably overlapped with the conductive portion 22A of each sidewall 220 of the isolation structure 22, thereby enhancing the conductive overlapping stability between the cathode 213 and the conductive portion 22A. It can be understood that a conductive overlapping stability between the cathode 213 of the sub-pixel 21 and the inclined sidewall 223 may be lower than a conductive overlapping stability between the cathode 213 of the sub-pixel 21 and the first sidewall 221, but may be higher than a conductive overlapping stability between the cathode 213 of the sub-pixel 21 and the second sidewall 222.

The sub-pixel 21 may substantially be in shape of a polygonal. The plurality of sub-pixel units 20 may form the repeating unit 30. The repeating unit 30 may be arranged in a rectangular pattern, which facilitates an array arrangement of the repeating units 30. A layout manner of the sub-pixels 21 may not be limited herein and may be selected based on actual needs.

In some embodiments, the sub-pixel 21 may substantially be in shape of an octagon. The isolation structure 22 may include two first sidewalls 221, two second sidewalls 222, and four inclined sidewalls 223. For each first sidewall 221 and an adjacent one of the second sidewalls 222, a corresponding one of the inclined sidewalls 223 may be disposed therebetween.

In other embodiments, as shown in FIG. 8, each repeating unit 30 may include the sub-pixels 21 of different shapes.

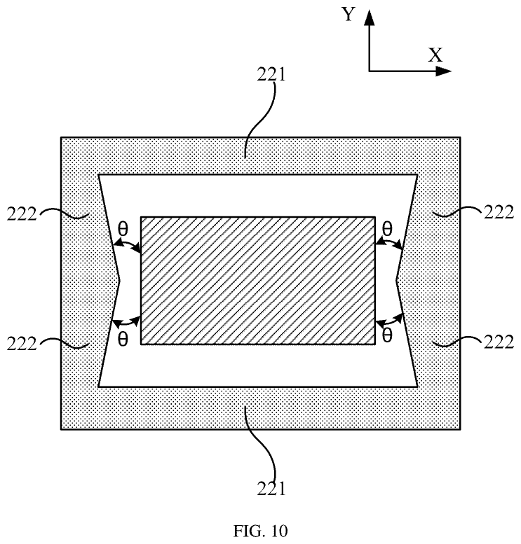

As shown in FIGS. 2, 4, 9, and 10, FIG. 9 is a schematic structural view of a fourth embodiment of a repeating unit according to the present disclosure, and FIG. 10 is a schematic structural view of a third embodiment of a sub-pixel unit according to the present disclosure.

Compared with the second embodiment of the repeating unit 30 provided by the present disclosure, the fourth embodiment of the repeating unit 30 provided by the present disclosure may be generally similar in structure with the difference being the following. In the planar direction substantially parallel to the pixel definition layer 10, an edge of the sub-pixel 21 and an edge of the first sidewall 221 that are adjacent to each other may be substantially arranged in parallel, while an edge of the sub-pixel 21 and an edge of the second sidewall 222 that are adjacent to each other may be arranged obliquely to each other.

In some embodiments, the inner side surface 2200 of the first sidewall 221 extends along the displacement direction X of the evaporation source 500. The second sidewall 222 may be the inclined sidewall 223. The extending direction of the inner side surface 2200 of the inclined sidewall 223 may intersect with both the length direction Y and the displacement direction X of the evaporation source 500. It may be understood that the isolation structure 22 includes the first sidewall 221 and the inclined sidewall 223.

In the planar direction substantially parallel to the pixel definition layer 10, a tilt angle θ between an edge of the sub-pixel 21 and an edge of the sidewall 220 that are adjacent to each other may be less than 15°. That is, the tilt angle θ between an edge of the sub-pixel 21 and an edge of the second sidewall 222 that are adjacent to each other may be less than 15°. Within each of the plurality of sub-pixel units 20, tilt angles θ between an edge of each second sidewall 222 and an adjacent edge of the sub-pixel 21 may be the same or different, which are not limited herein and may be selected based on actual needs.

The sub-pixel 21 may substantially be in shape of a rectangle. A shorter side of the rectangle may extend in a direction substantially parallel to the length direction Y of the evaporation source 500. A longer side of the rectangle may extend in a direction substantially parallel to the displacement direction X of the evaporation source 500.

While the isolation structure 22 remains on the first sidewall 221, the inner side surface 2200 of the second sidewall 222 may be arranged obliquely relative to an edge of the sub-pixel 21, thereby improving the conductive overlapping stability between the second sidewall 222 and the cathode 213 of the sub-pixel 21.

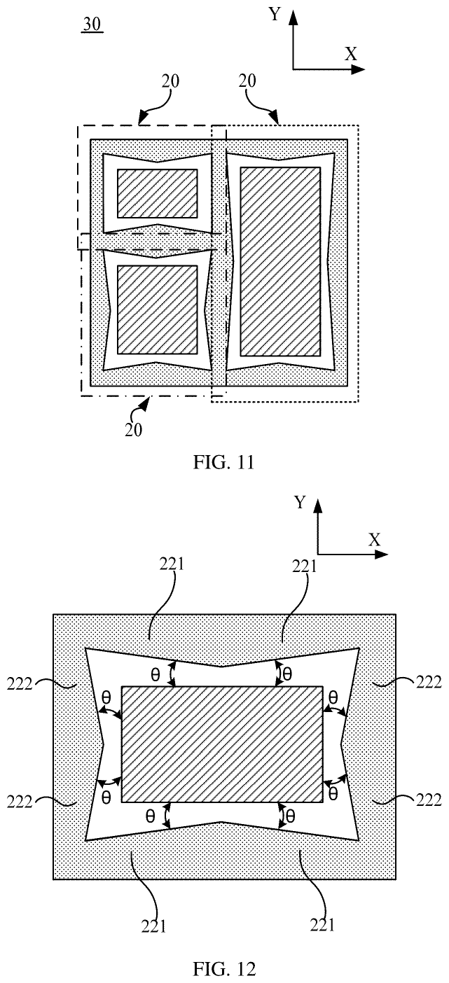

As shown in FIGS. 2, 4, 11, and 12, FIG. 11 is a schematic structural view of a fifth embodiment of a repeating unit according to the present disclosure, and FIG. 12 is a schematic structural view of a fourth embodiment of a sub-pixel unit according to the present disclosure.

Compared with the second embodiment of the repeating unit 30 provided by the present disclosure, the fifth embodiment of the repeating unit 30 provided by the present disclosure may be generally similar in structure with the difference being the following. In the planar direction substantially parallel to the pixel definition layer 10, an edge of the sub-pixel 21 and an edge of the sidewall 220 that are adjacent to each other are arranged obliquely.

In some embodiments, each of the first sidewall 221 and the second sidewall 222 is the inclined sidewall 223. An extending direction of the inner side surface 2200 of the inclined sidewall 223 may intersect with both the length direction Y and the displacement direction X of the evaporation source 500.

In the planar direction substantially parallel to the pixel definition layer 10, the tilt angle θ between an edge of the sub-pixel 21 and an edge of the sidewall 220 may be less than 15°. That is, the tilt angle θ between an edge of the sub-pixel 21 and an edge of the first sidewall 221 may be less than 15°. The tilt angle θ between an edge of the sub-pixel 21 and an edge of the second sidewall 222 that are adjacent to each other may be less than 15°.

For different sub-pixel units 20, the tilt angles θ between edges of the sub-pixel 21 and edges of the sidewall 220 that are adjacent to each other may be the same or different, which is not limited herein and may be selected based on actual needs. Within each of the plurality of sub-pixel units 20, the tilt angles θ between different edges of sub-pixel 21 and the sidewalls 220 adjacent thereto may be the same or different.

The sub-pixel 21 may substantially be in shape of a rectangle. A shorter side of the rectangle may extend in a direction substantially parallel to the length direction Y of the evaporation source 500. A longer side of the rectangle may extend in a direction substantially parallel to the displacement direction X of the evaporation source 500.

The edges of the sub-pixel 21 may be arranged corresponding to two sidewalls 220 of the isolation structure 22. Ends of the two sidewalls 220 that are adjacent and connected to each other may be disposed in adjacent to the sub-pixel 21. Ends of the two sidewalls 220 that are away from each other may be disposed away from the sub-pixel 21.

It should be understood that, in other embodiments, each edge of the sub-pixel 21 may correspond to a corresponding one sidewall 220 of the isolation structure 22.

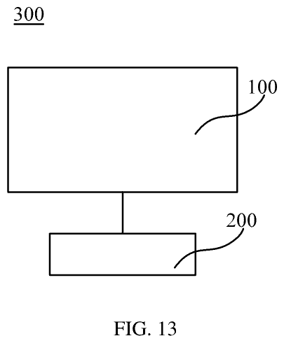

As shown in FIG. 13, FIG. 13 is a schematic structural view of a display device according to some embodiments of the present disclosure.

Some embodiments of the present disclosure may provide a display device 300. The display device 300 may include a main board 200 and the above-mentioned display panel 100.

The main board 200 may be electrically connected to the display panel 100 and may be configured to transmit various required signals to the display panel 100 so as to control the display panel 100 to display an image. For example, the signals for driving the display panel 100 may include a clock signal (CK), a common voltage signal (Vss), a power voltage signal (VDD), a data signal (Data), etc.

In the above embodiments, different aspects are emphasized respectively. Portions not described in detail in one embodiment may refer to relevant descriptions in other embodiments.

The above are merely exemplary embodiments of the present disclosure and should not be construed as limiting the scope of the present disclosure. Based on the description and drawings of the present disclosure, any equivalent structural or process modifications, or any direct or indirect applications in other related technical fields, shall fall within the scope of the present disclosure.

1. A display panel, comprising:
a pixel defining layer, defining a plurality of pixel openings; and
a plurality of sub-pixel units, each of the plurality of sub-pixel units comprising:
a sub-pixel, disposed in a corresponding one of the plurality of pixel openings, wherein a light-emitting layer and a cathode of the sub-pixel are sequentially evaporated on the corresponding one of the plurality of pixel openings through an evaporation source; and
an isolation structure, protruding from the pixel defining layer and surrounding the corresponding one of the plurality of pixel openings, wherein a sidewall of the isolation structure comprises a conductive portion and a shielding structure shielding the conductive portion;
wherein in a planar direction substantially parallel to the conductive portion, the shielding structure extends beyond the conductive portion; the conductive portion is electrically connected to the sub-pixel; and the sidewall comprises a first sidewall and a second sidewall;
wherein an inner side surface of the first sidewall extends in a displacement direction of the evaporation source; in the first sidewall, a distance between an edge of the shielding structure and an edge of the conductive portion that are adjacent to each other is a first distance; in the second sidewall, a distance between an edge of the shielding structure and an edge of the conductive portion that are adjacent to each other is a second distance; and within each of the plurality of sub-pixel units, the second distance is greater than the first distance;
or,
in a planar direction substantially parallel to the pixel defining layer, an edge of the sub-pixel extending in a length direction of the evaporation source and an edge of the sidewall that are adjacent to each other are obliquely disposed to each other.

2. The display panel as claimed in claim 1, wherein in the planar direction substantially parallel to the pixel defining layer, the edge of the shielding structure and the edge of the conductive portion that are adjacent to each other within the same sidewall are substantially arranged in parallel; and a distance between the edge of the shielding structure and the edge of the conductive portion that are adjacent to each other is a preset value, the preset value is greater than or equal to 0.3 μm and less than or equal to 1.2 μm.

3. The display panel as claimed in claim 1, wherein a difference between the second distance and the first distance is less than or equal to 0.3 μm.

4. The display panel as claimed in claim 2, wherein in the planar direction substantially parallel to the pixel defining layer, an edge of the sub-pixel and an edge of sidewall that are adjacent to each other are substantially arranged in parallel; and an inner side surface of the second sidewall extends in the length direction of the evaporation source.

5. The display panel as claimed in claim 4, wherein the sidewall further comprises an inclined sidewall, an extending direction of an inner side surface of the inclined sidewall intersects with both the length direction and the displacement direction of the evaporation source.

6. The display panel as claimed in claim 5, wherein an included angle between the extending direction of the inner side surface of the inclined sidewall and the length direction of the evaporation source is greater than 5° and less than 20°.

7. The display panel as claimed in claim 6, wherein in the inclined sidewall, a distance between an edge of the shielding structure and an edge of the conductive portion that are adjacent to each other is a third distance; and the third distance is greater than or equal to the first distance.

8. The display panel as claimed in claim 1, wherein in a planar direction substantially parallel to the pixel defining layer, a tilt angle between an edge of the sub-pixel and an edge of the sidewall that are adjacent to each other is less than 15°.

9. The display panel as claimed in claim 8, wherein the sub-pixel is substantially in shape of a rectangle, a shorter side of the rectangle extends in a direction substantially parallel to the length direction of the evaporation source, and a longer side of the rectangle extends in a direction substantially parallel to the displacement direction of the evaporation source.

10. The display panel as claimed in claim 9, wherein the inner side surface of the first sidewall extends in the displacement direction of the evaporation source; in the planar direction substantially parallel to the pixel defining layer, an edge of the sub-pixel and an edge of the first sidewall that are adjacent to each other are substantially arranged in parallel, and an edge of the sub-pixel and an edge of the second sidewall that are adjacent to each other are obliquely disposed to each other;
or,
in the planar direction substantially parallel to the pixel defining layer, an edge of the sub-pixel and an edge of the sidewall that are adjacent to each other are obliquely disposed to each other.

11. A display device, comprising a main board and a display panel, and the display panel comprising:
a pixel defining layer, defining a plurality of pixel openings; and
a plurality of sub-pixel units, each of the plurality of sub-pixel units comprising:
a sub-pixel, disposed in a corresponding one of the plurality of pixel openings, wherein a light-emitting layer and a cathode of the sub-pixel are sequentially evaporated on the corresponding one of the plurality of pixel openings through an evaporation source; and
an isolation structure, protruding from the pixel defining layer and surrounding the corresponding one of the plurality of pixel openings, wherein a sidewall of the isolation structure comprises a conductive portion and a shielding structure shielding the conductive portion;
wherein in a planar direction substantially parallel to the conductive portion, the shielding structure extends beyond the conductive portion; the conductive portion is electrically connected to the sub-pixel; and the sidewall comprises a first sidewall and a second sidewall;
wherein an inner side surface of the first sidewall extends in a displacement direction of the evaporation source; in the first sidewall, a distance between an edge of the shielding structure and an edge of the conductive portion that are adjacent to each other is a first distance; in the second sidewall, a distance between an edge of the shielding structure and an edge of the conductive portion that are adjacent to each other is a second distance; and within each of the plurality of sub-pixel units, the second distance is greater than the first distance;
or,
in a planar direction substantially parallel to the pixel defining layer, an edge of the sub-pixel extending in a length direction of the evaporation source and an edge of the sidewall that are adjacent to each other are obliquely disposed to each other.

12. The display device as claimed in claim 11, wherein in the planar direction substantially parallel to the pixel defining layer, the edge of the shielding structure and the edge of the conductive portion that are adjacent to each other within the same sidewall are substantially arranged in parallel; and a distance between the edge of the shielding structure and the edge of the conductive portion that are adjacent to each other is a preset value, the preset value is greater than or equal to 0.3 μm and less than or equal to 1.2 μm.

13. The display device as claimed in claim 11, wherein a difference between the second distance and the first distance is less than or equal to 0.3 μm.

14. The display device as claimed in claim 12, wherein in the planar direction substantially parallel to the pixel defining layer, an edge of the sub-pixel and an edge of sidewall that are adjacent to each other are substantially arranged in parallel; and an inner side surface of the second sidewall extends in the length direction of the evaporation source.

15. The display device as claimed in claim 14, wherein the sidewall further comprises an inclined sidewall, an extending direction of an inner side surface of the inclined sidewall intersects with both the length direction and the displacement direction of the evaporation source.

16. The display device as claimed in claim 15, wherein an included angle between the extending direction of the inner side surface of the inclined sidewall and the length direction of the evaporation source is greater than 5° and less than 20°.

17. The display device as claimed in claim 16, wherein in the inclined sidewall, a distance between an edge of the shielding structure and an edge of the conductive portion that are adjacent to each other is a third distance; and the third distance is greater than or equal to the first distance.

18. The display device as claimed in claim 11, wherein in a planar direction substantially parallel to the pixel defining layer, a tilt angle between an edge of the sub-pixel and an edge of the sidewall that are adjacent to each other is less than 15°.

19. The display device as claimed in claim 18, wherein the sub-pixel is substantially in shape of a rectangle, a shorter side of the rectangle extends in a direction substantially parallel to the length direction of the evaporation source, and a longer side of the rectangle extends in a direction substantially parallel to the displacement direction of the evaporation source.

20. The display device as claimed in claim 19, wherein the inner side surface of the first sidewall extends in the displacement direction of the evaporation source; in the planar direction substantially parallel to the pixel defining layer, an edge of the sub-pixel and an edge of the first sidewall that are adjacent to each other are substantially arranged in parallel, and an edge of the sub-pixel and an edge of the second sidewall that are adjacent to each other are obliquely disposed to each other;
or,
in the planar direction substantially parallel to the pixel defining layer, an edge of the sub-pixel and an edge of the sidewall that are adjacent to each other are obliquely disposed to each other.
